(19) United States
(12) Patent Application Publication
(10) Pub. No.: US 2005/0140403 A1
(43) Pub. Date: Jun. 30, 2005

(54) Internal clock doubler

(75) Inventor: Kyoung Ho Lee, Chungcheongbuk-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 10/879,524

(22) Filed: Jun. 30, 2004

(30) Foreign Application Priority Data
Dec. 26, 2003 (KR) 2003-0097418

(51) Int. Cl. H03B 19/00

(52) U.S. Cl. 327/122

(57) ABSTRACT

An internal clock doubler comprises a clock delay unit, an edge detecting unit and an output driver. The clock delay unit delays a clock signal for a predetermined delay time and outputs a delay clock signal. The edge detecting unit detects rising and falling edges of the clock signal in response to the delay clock signal and outputs a rising pulse signal and a falling pulse signal. The output driver outputs a double clock signal toggled at every rising edge and every falling edge of the clock signal in response to the rising pulse signal and the falling pulse signal. As a result, since a double clock signal having double frequency of an internal clock signal is generated without external input of an additional clock signal through an additional pad, a stable high-speed test can be performed on a semiconductor memory device.

### BACKGROUND OF THE INVENTION

1. Field of the Invention

The present invention generally relates to an internal clock doubler, and more specifically, to a technology of generating a double clock signal having double frequency of an internal clock signal without inputting an external clock signal through an addition pad pad, thereby performing a stable test when a semiconductor memory device performs a high speed operation.

2. Description of the Prior Art

In general, a high speed test of 100 MHz is required in a wafer level of a DRAM. However, since most line test equipment has a limited tCK to the maximum of 16 ns, it is impossible to perform a test on a wafer when a semiconductor memory device performs a high speed operation. In order to improve the problem, a clock doubler with a double clock signal having double frequency of a internal clock has been used.

A conventional clock doubler generates the double clock signal having double frequency of the clock signal CLK by using the clock signal CLK and a clock bar signal CLKB having the opposite phase to that of the clock signal CLK.

However, the conventional clock doubler comprises an additional pad to receive the clock bar signal.

As a result, the additional pad occupies a large area in the semiconductor memory device

To resolve the problem, the conventional clock doubler receives the clock bar signal CLKB through a pad which has been used for another function.

But, the pad for another function cannot be tested while the pad for another function receives the clock bar signal CLKB.

For example, when a clock pad receives the clock bar signal CLKB, the clock pad cannot be tested while the clock pad receives the clock bar signal CLKB.

Additionally, since the conventional clock doubler regulates the frequency of a clock by using the clock signal CLK and the clock bar signal CLKB inputted from a tester, the pulse width of the clock signal is determined depending on that of the clock signal CLK and the clock bar signal CLKB.

### SUMMARY OF THE INVENTION

Accordingly, it is an object of the present invention to generate a double clock signal having double frequency of an internal clock signal without receiving an additional clock signal through an additional pad or a using pad.

It is another object of the present invention to generate the double clock signal by using a clock signal delayed for a predetermined time to control a pulse width of the double clock signal depending on delay time of the clock signal.

In an embodiment, an internal clock doubler comprises clock delay unit, an edge detecting unit and an output driver. The clock delay unit delays a clock signal for a predetermined delay time and outputs a delay clock signal. The edge detecting unit senses rising and falling edges of the clock signal in response to the delay clock signal and outputs a rising pulse signal and a falling pulse signal. The output driver outputs a double clock signal toggled at every rising edge and every falling edge of the clock signal in response to the rising pulse signal and the falling pulse signal.

### BRIEF DESCRIPTION OF THE DRAWINGS

Other aspects and advantages of the present invention will become apparent upon reading the following detailed description and upon reference to the drawings in which:

FIG. 1 is a diagram illustrating a semiconductor memory device including an internal clock doubler according to an embodiment of the present invention;

FIG. 2 is a circuit diagram illustrating the internal clock doubler of FIG. 1; and

FIG. 3 is a timing diagram illustrating the operation of the internal clock doubler of FIG. 1.

### DETAILED DESCRIPTION OF THE PREFERRED EMBODIMENTS

The present invention will be described in detail with reference to the accompanying drawings.

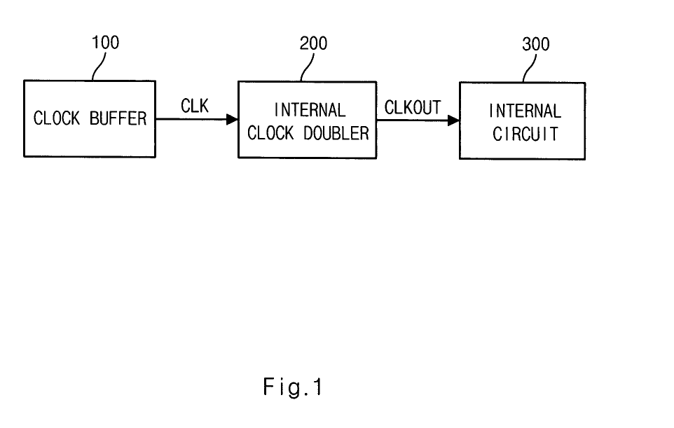

FIG. 1 is a diagram illustrating a semiconductor memory device including an internal clock doubler according to an embodiment of the present invention.

In an embodiment, the semiconductor memory device comprises a clock buffer 100, an internal clock doubler 200 and an internal circuit 300.

The clock buffer 100 outputs a clock signal CLK, and the internal clock doubler 200 outputs a double clock signal CLKOUT having double frequency of the clock signal CLK.

The internal circuit 300 performs a high speed operation at a test by using the double clock signal CLKOUT outputted from the clock doubler 200.

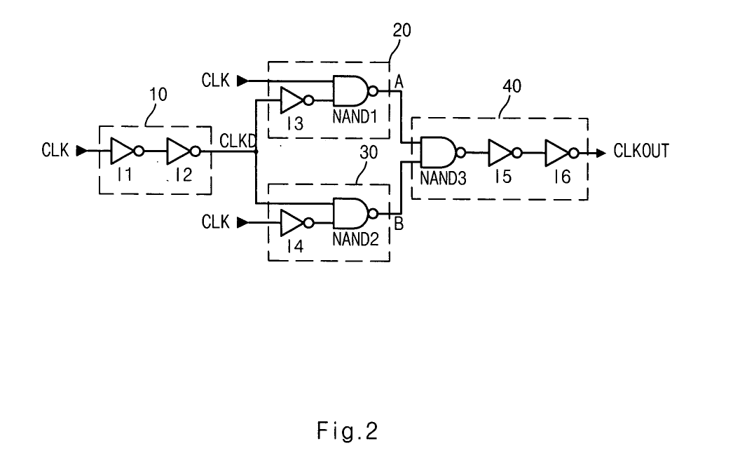

FIG. 2 is a circuit diagram illustrating the internal clock doubler 200 of FIG. 1.

The internal clock doubler 200 comprises a clock delay unit 10, edge detectors 20 and 30, and an output drivier 40.

The clock delay unit 10 delays the clock signal CLK, and outputs a delay clock signal CLKD. Although the clock delay unit 10 comprises inverters I1 and I2 in FIG. 1, a pulse width of the double clock signal CLKOUT can be adjusted by changing or regulating the number of inverters. Accordingly, another example of the clock delay unit 10 can be embodied.

The edge detectors 20 and 30 detect rising and falling edges of the clock signal CLK.

The rising edge detector 20, which comprises an inverter I3 for inverting the delay clock signal CLKD and a NAND gate NAND1 for performing a NAND operation on an output signal from the inverter I3 and the clock signal, detects the rising edge of the clock signal CLK to output a pulse signal A.

The falling edge detector 30, which comprises an inverter I4 for inverting the clock signal CLK and a NAND gate NAND2 for performing a NAND operation on an output signal from the inverter I4 and the delay clock signal CLKD, detects the falling edge of the clock signal CLK to output a pulse signal B.

The output driver 40 comprises a NAND gate NAND3 and inverters I5 and I6. The NAND gate NAND3 performs a NAND operation on the pulse signals A and B. The inverters I5 and I6 connected serially drive an output signal from the NAND gate NAND3, and outputs the double clock signal CLKOUT.

Here, the clock signal CLK is the basis to synchronize various signals in test equipment and chips, and the double clock signal CLKOUT is applied to the internal circuit at a high speed test.

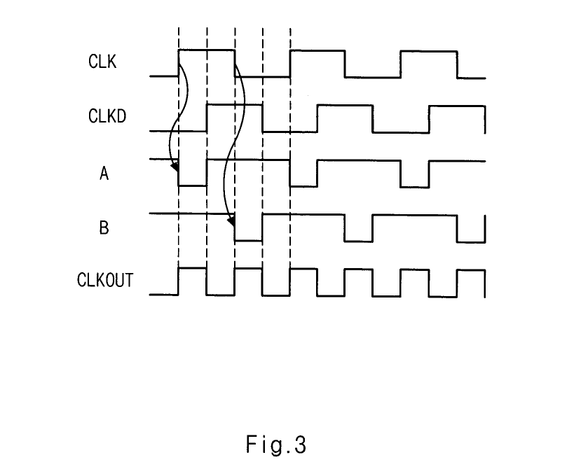

FIG. 3 is a timing diagram illustrating the operation of the internal clock doubler of FIG. 1.

The clock delay unit 10 delays the clock signal CLK for a predetermined time, and outputs the delay clock signal CLKD. The rising edge detector 20 outputs the pulse signal A having a low pulse width from the rising edge of the clock signal CLK to the rising edge of the delay clock signal. The falling edge detector 30 outputs the pulse signal B having a low pulse width from the falling edge of the clock signal CLK to the falling edge of the delay clock signal CLK.

Thereafter, an output buffer circuit outputs the double clock signal CLKOUT whenever the pulse signal A or B transits to a low level.

More specifically, as shown in FIG. 3, if the clock signal CLK is at a high level and the delay clock signal CLKD is at a low level, the NAND gate NAND1 outputs the pulse signal A having the low level, the NAND gate NAND2 outputs the pulse signal B having the high level, and the NAND gate NAND3 outputs the double clock signal CLKOUT having a high level.

On the other hand, if the clock signals CLK and the delay clock signal CLKD are at the high level, the NAND gates NAND1 and NAND2 outputs the pulse signals A and B having the high level, and the NAND gate NAND3 outputs the double clock signal CLKOUT having a low level.

Thereafter, if the clock signal CLK transits from the high level to the low level and the delay clock signal CLKD is at the high level, the edge detector 20 outputs the pulse signal A having the high level, and the edge detector 30 outputs the pulse signal B having the low level. As a result, the NAND gate NAND3 outputs the double clock signal CLKOUT having the high level.

Then, if the clock signal CLK transits from the low level to the high level and the delay clock signal CLKD is at the low level, the edge detector 20 outputs the pulse signal A having the low level, and the edge detector 30 outputs the pulse signal B having the high level. As a result, the NAND gate NAND3 outputs the double clock signal CLKOUT having the high level.

As described above, whenever the pulse signals A and B are enabled, the double clock signal CLKOUT is enabled so that the double clock signal CLKOUT has double frequency of the clock signal CLK. Here, the period from the rising edge of the clock signal CLK to the rising edge of the delay clock signal CLKD or from the falling edge of the clock signal CLK to the falling edge of the delay clock signal CLKD corresponds to the pulse width of the pulse signal A or B. The pulse width is determined by the delay period of the delay clock signal CLKD. In this way, the pulse width of the double clock signal CLKOUT can be adjusted by regulating the delay period of the delay clock signal CLKD.

Accordingly, an internal clock doubler according to an embodiment of the present invention generates a double clock signal CLKOUT having double frequency of a clock signal CLK without external input of an additional clock signal through an additional pad, thereby enabling a high speed test of a semiconductor memory device.

While the invention is susceptible to various modifications and alternative forms, specific embodiments have been shown by way of example in the drawings and described in detail herein. However, it should be understood that the invention is not limited to the particular forms disclosed. Rather, the invention covers all modifications, equivalents, and alternatives falling within the spirit and scope of the invention as defined in the appended claims.

1. An internal clock doubler comprising:
a clock delay unit for delaying a clock signal for a predetermined delay time and outputting a delay clock signal;
an edge detecting unit for detecting rising and falling edges of the clock signal in response to the delay clock signal and outputting a rising pulse signal and a falling pulse signal; and
an output driver for outputting a double clock signal toggled at every rising edge and every falling edge of the clock signal in response to the rising pulse signal and the falling pulse signal.

2. The internal clock doubler according to claim 1, wherein the clock delay unit comprises a plurality of inverters.

3. The internal clock doubler according to claim 1, wherein each of the rising pulse signal and the falling pulse signal has a pulse width corresponding to the delay time of the clock delay unit.

4. The internal clock doubler according to claim 1, wherein the edge detecting unit comprises:
a rising edge detector for outputting the rising pulse signal in response to the delay clock signal; and
a falling edge detector for outputting the falling pulse signal in response to the delay clock signal.

5. The internal clock doubler according to claim 4, wherein the rising edge detector comprises:
an inverting unit for inverting the delay clock signal; and
a NAND gate for performing a NAND operation on an output signal from the inverting unit and the clock signal.

6. The internal clock doubler according to claim 4, wherein the falling edge detector comprises:
an inverting unit for inverting the clock signal; and
a NAND gate for performing a NAND operation on an output signal from the inverting unit and the delay clock signal.

7. The internal clock doubler according to claim 1, wherein the output driver comprises:
a NAND gate for performing a NAND operation on the rising pulse signal and the falling pulse signal; and
a driving unit for driving an output signal from the NAND gate.

8. The internal clock doubler according to claim 7, wherein the driving unit comprises the even number of inverters.
